(19) United States
(12) Patent Application Publication
(10) Pub. No.: US 2024/0272245 A1
(43) Pub. Date: Aug. 15, 2024

(54) SEMICONDUCTOR MANUFACTURING DEVICE AND SEMICONDUCTOR MANUFACTURING METHOD

(71) Applicant: SAMSUNG ELECTRONICS CO., LTD., Suwon-si (KR)

(72) Inventors: KEN OZAWA, Yokohama-shi (JP); Kenji Suzuki, Yokohama-shi (JP); Shinji Ueyama, Yokohama-shi (JP)

(21) Appl. No.: 18/427,676

(22) Filed: Jan. 30, 2024

(30) Foreign Application Priority Data
Feb. 10, 2023 (JP) 2023-019417
Oct. 5, 2023 (KR) 10-2023-0132138

(51) Int. Cl. G01R 33/032

(52) U.S. Cl. CPC G01R 33/0325

(57) ABSTRACT

A semiconductor manufacturing device includes a detection unit that detects an extinction response of a perpendicular magnetic anisotropy PMA film in a sample from a polar Kerr effect signal, and a derivation unit that derives an anisotropic magnetic field (Hk) of the PMA film by extrapolating and fitting the detected extinction response, in magneto-optical Kerr effect measurement that uses a plurality of electromagnets that electrically apply magnetic fields to the sample on the stage by convert a perpendicular magnetic field that includes a vertical component normal to an upper surface of a stage, and a horizontal magnetic field parallel to the upper surface of the stage.

### CROSS-REFERENCE TO RELATED APPLICATION(S)

This application claims priority under 35 U.S.C. 119(a) from Korean Patent Application No. 10-2023-0132138, filed on Oct. 5, 2023 in the Korean Intellectual Property Office, and Japanese Patent Application No. 2023-019417, filed on Feb. 10, 2023 in the Japan Patent Office, the contents of both of which are herein incorporated by reference in their entireties.

### TECHNICAL FIELD

Embodiments of the present inventive concept are directed to a semiconductor manufacturing device and a semiconductor manufacturing method.

### DISCUSSION OF THE RELATED ART

In general, in a perpendicular magnetic anisotropy film, hereinafter referred to as a PMA film, for a spin transfer torque magnetoresistive random access memory (STT-MRAM), a vibrating sample magnetometer (VSM) is a representative example of a method of evaluating anisotropic magnetic fields (Hk). However, the size of a sample used for measurement in VSM is limited to approximately 10 mm. Therefore, it may be challenging to evaluate an anisotropic magnetic field (Hk) in semiconductor wafers such as φ200 mm and φ300 mm. Therefore, evaluation of the anisotropic magnetic field (Hk) by VSM is a so-called destructive test in which the sample is broken into small pieces.

In addition, a device that detects the magneto-optical Kerr effect (MOKE or Kerr effect) that occurs when a magnetic field is applied to a sample is a classic magneto-optical measurement device. For convenience of description, this device is called a MOKE device. A MOKE device can perform non-destructive testing by devising the structure of an electromagnet.

When a semiconductor wafer is used as a sample, the MOKE device is made to have an electromagnet disposed on the surface of the semiconductor wafer, rather than an opposing electromagnet. In this case, the MOKE device includes two or four electromagnets that includes a magnetic core called a yoke and a coil wound around the magnetic core. Such MOKE devices have already been commercialized. Hereinafter, a plurality of electromagnets disposed on the surface of a semiconductor wafer are referred to as leakage magnetic field electromagnets, and a magnetic field formed by the leakage magnetic field electromagnets is referred to as a leakage magnetic field.

### SUMMARY

Embodiments of the present inventive concept provide a semiconductor manufacturing device and a semiconductor manufacturing method in which magnetic properties can be non-destructively measured with high precision.

According to embodiments, a semiconductor manufacturing device includes a detection unit that detects an extinction response of a perpendicular magnetic anisotropy film in a sample, and a derivation unit that derives an anisotropic magnetic field of the perpendicular magnetic anisotropy film by extrapolating and fitting the extinction response, in magneto-optical Kerr effect measurement that uses a plurality of electromagnets that electrically switch between a first magnetic field that includes a vertical component normal to an upper surface of a stage and a second magnetic field that includes a horizontal component parallel to the upper surface of the stage, as magnetic fields applied to the sample on the stage.

The semiconductor manufacturing device further includes a control unit that controls a current that flows through the plurality of electromagnets, saturates a vertical magnetization of the perpendicular magnetic anisotropy film by applying to the sample the first magnetic field whose magnitude is greater than a coercivity of the perpendicular magnetic anisotropy film, sets a magnitude of the first magnetic field to be 0, switches to the second magnetic field, increases a magnitude of the second magnetic field from 0, and performs a bipolar sweep that includes increasing and decreasing the magnitude of the second magnetic field a plurality of times. The detection unit detects the extinction response from a polar Kerr effect signal measured by the bipolar sweep.

The derivation unit derives the anisotropic magnetic field from the second magnetic field whose magnetization magnitude is 0 by extrapolating and fitting the extinction response.

The semiconductor manufacturing device further includes a control unit that controls a current flowing through the plurality of electromagnets, and the plurality of electromagnets are disposed on a surface of the sample that includes a wafer that has a front surface and a back surface, and applies the first magnetic field and the second magnetic field to the sample from the surface of the sample. Each electromagnet of the plurality of electromagnets includes a yoke and a coil, and the control unit applies the first magnetic field that saturates a vertical magnetization of the perpendicular magnetic anisotropy film and the second magnetic field that obtains an extinction response measurement, by controlling a direction and a magnitude of the current flowing through each coil.

The semiconductor manufacturing device includes a magnetic field sensor disposed adjacent to the sample, and a magnetic field direction measuring device that measures components of the second magnetic field other than the horizontal component.

Based on the second magnetic field measured with the magnetic field direction measuring device, the control unit controls the current flowing in each coil such that the vertical component of the second magnetic field is minimized.

Based on the second magnetic field measured with the magnetic field direction measuring device, the stage controls a tilt of the sample such that the horizontal component of the second magnetic field is parallel to a sample surface.

The semiconductor manufacturing device further includes abeam steering mechanism that moves an optical path of illumination light used for the magneto-optical Kerr effect measurement.

Based on the second magnetic field measured with the magnetic field direction measuring device, the beam steering mechanism moves a spot position of the illumination light on the sample to a position in which the vertical component of the second magnetic field is minimized, by controlling a beam angle control by the beam steering.

The control unit controls current flowing in each coil such that the vertical component of the second magnetic field is minimized at predetermined intervals during continuous magneto-optical Kerr effect measurements.

The stage controls the tilt of the sample such that the horizontal component of the second magnetic field is parallel to the sample surface at predetermined intervals during continuous magneto-optical Kerr effect measurements.

The beam shifter moves the spot position of the illumination light on the sample to a position in which the vertical component of the second magnetic field is minimized, at predetermined intervals during continuous magneto-optical Kerr effect measurements.

The semiconductor manufacturing device includes an image acquisition unit that acquires an image of the sample that includes a plurality of regions of interest, and an image analysis unit that analyzes a change in a luminance value for each region of interest due to a magneto-optical Kerr effect. The control unit applies the first magnetic field to the sample such that the image acquisition unit acquires a hysteresis loop of the luminance value for each region of interest, switches to the second magnetic field and increases a magnitude of the second magnetic field from 0, and performs a bipolar sweep that includes increasing and decreasing the magnitude of the second magnetic field The image analysis unit obtains a change range of the luminance value for each region of interest from an extinction response of the luminance value, detects a reference region of interest in which the vertical component of the second magnetic field is minimized from positions of the plurality of regions of interest in which magnetization reversal occurred in the bipolar sweep, extrapolates and fits the luminance value of the reference region of interest, and acquires the anisotropic magnetic field from the second magnetic field in which an amount of change in luminance is ½ of a change.

The semiconductor manufacturing device further includes a beam steering that moves an optical path of an illumination light used to measure the magneto-optical Kerr effect, and the beam steering moves a spot position in which the vertical component of the second magnetic field is minimized.

The stage includes additional heating and temperature measuring functions, and the detection unit detects a thermal stability index from a relationship between a temperature of the sample and the anisotropic magnetic field.

According to embodiments, a semiconductor manufacturing method includes detecting an extinction response of a perpendicular magnetic anisotropy film in a sample from a polar Kerr effect signal in a magneto-optical Kerr effect measurement that uses a plurality of electromagnets that electrically switch between applying a first magnetic field and a second magnetic field to the sample on a stage, wherein the magnetic field includes a vertical component normal to an upper surface of the stage and the second magnetic field includes a horizontal component parallel to the upper surface of the stage, and deriving an anisotropic magnetic field of the perpendicular magnetic anisotropy film by extrapolating and fitting the detected extinction response.

Detecting the extinction response of the perpendicular magnetic anisotropy film in the sample includes applying the first magnetic field to the sample, wherein a magnitude of the first magnetic field is greater larger than a coercivity (Hc) of the perpendicular magnetic anisotropy film, saturating vertical magnetization of the perpendicular magnetic anisotropy film, setting a magnitude of the first magnetic field to 0, switching to the second magnetic field, increasing a magnitude of the second magnetic field from 0, performing a bipolar sweep that includes increasing and decreasing the magnitude of the second magnetic field a plurality of times, and detecting an extinction response from the polar Kerr effect signal measured by the bipolar sweep.

Deriving the anisotropic magnetic field of the perpendicular magnetic anisotropy film includes deriving the anisotropic magnetic field from the second magnetic field in which a magnetization amount is 0, by extrapolating and fitting the extinction response.

The plurality of electromagnets are disposed on a surface of the sample that includes a wafer that has a front surface and a back surface, and apply the first magnetic field and the second magnetic field to the sample from the surface of the sample. Each electromagnet may include a yoke and a plurality of coils, and detecting the extinction response of the perpendicular magnetic anisotropy film in the sample includes applying the first magnetic field and the second magnetic field to the sample, by controlling a direction and a magnitude of current flowing in each coil.

Detecting the extinction response of the perpendicular magnetic anisotropy film in the sample further includes measuring components other than the horizontal component in the second magnetic field by a magnetic field direction measuring device that includes a magnetic field sensor disposed adjacent to the sample.

Detecting the extinction response of the perpendicular magnetic anisotropy film in the sample further includes controlling a current flowing through each coil such that the vertical component of the second magnetic field is minimized, based on the second magnetic field measured by the magnetic field direction measuring device.

Detecting the extinction response of the perpendicular magnetic anisotropy film in the sample further includes controlling, by the stage, a tilt of the sample such that a horizontal component of the second magnetic field is parallel to a sample film surface, based on the second magnetic field measured with the magnetic field direction measuring device.

Detecting the extinction response of the perpendicular magnetic anisotropy film in the sample further includes moving a spot position of the illumination light on the sample, that measures the magneto-optical Kerr effect to a position in which the vertical component of the second magnetic field is minimized in a measurement position illuminated by the illumination light, based on the second magnetic field measured with the magnetic field direction measuring device.

Detecting the extinction response of the perpendicular magnetic anisotropy film in the sample further includes controlling a current flowing in each coil such that the vertical component of the second magnetic field is minimized at predetermined intervals during continuous magneto-optical Kerr effect measurements.

Detecting the extinction response of the perpendicular magnetic anisotropy film in the sample further includes controlling, by the stage, a tilt of the sample such that the horizontal component becomes parallel to a sample film surface at predetermined intervals during the continuous magneto-optical Kerr effect measurements.

Detecting the extinction response of the perpendicular magnetic anisotropy film in the sample further includes moving a spot position of the illumination light to a position in which the vertical component of the second magnetic field is minimized at predetermined intervals during the continuous magneto-optical Kerr effect measurements.

The semiconductor manufacturing method further includes acquiring an image of the sample that includes a plurality of regions of interest, and analyzing a change in a luminance value for each region of interest due to the magneto-optical Kerr effect. Acquiring the image of the sample includes applying the first magnetic field to the sample such that a hysteresis loop of the luminance value is obtained for each region of interest, switching to the second magnetic field, increasing a magnitude of the second magnetic field from 0, and performing a bipolar sweep that includes increasing and decreasing a magnitude of the second magnetic field. Analyzing the change in the luminance value for each region of interest due to the magneto-optical Kerr effect includes acquiring a change range of the luminance value for each region of interest from the hysteresis loop of the luminance value, detecting a reference region of interest in which the vertical component of the second magnetic field is minimized from positions of the plurality of regions of interest in which magnetization reversal occurred in the bipolar sweep, extrapolating and fitting the luminance value of the reference region of interest, and acquiring the anisotropic magnetic field from the second magnetic field in which an amount of change in luminance is ½ of a change range.

Detecting the extinction response of the perpendicular magnetic anisotropy film in the sample further includes moving an optical path of illumination light used for measuring the magneto-optical Kerr effect to the reference region of interest.

The stage includes additional heating and temperature measuring functions, and the semiconductor manufacturing method further includes detecting a thermal stability index from a relationship between a temperature of the sample and the anisotropic magnetic field.

### BRIEF DESCRIPTION OF DRAWINGS

FIG. 1 illustrates a semiconductor manufacturing device according to an embodiment.

FIG. 2 is a perspective view of a magnetic field generating unit in a semiconductor manufacturing device according to an embodiment.

FIG. 3 illustrates a magnetic field generated by a magnetic field generating unit in a semiconductor manufacturing device according to an embodiment.

FIG. 4 illustrates a magnetic field generated by a magnetic field generating unit in a semiconductor manufacturing device according to an embodiment.

FIG. 5 illustrates a hysteresis loop of the vertical magnetization characteristics of a sample in the semiconductor manufacturing device according to an embodiment of the present disclosure.

FIG. 6 is a flow chart of a semiconductor manufacturing method according to an embodiment.

FIG. 7 is a flow chart of a method of detecting an extinction response in a semiconductor manufacturing method according to an embodiment.

FIG. 8 illustrates a magnetic field applied to a sample in a semiconductor manufacturing device according to an embodiment of the present disclosure.

FIG. 9 illustrates the vertical magnetization of a sample in a semiconductor manufacturing device according to an embodiment of the present disclosure.

FIG. 10 illustrates the vertical magnetization of a sample in a semiconductor manufacturing device according to an embodiment of the present disclosure.

FIG. 11 illustrates a magnetic field applied to a sample in a semiconductor manufacturing device according to an embodiment.

FIG. 12 illustrates the vertical magnetization of a sample in a semiconductor manufacturing device according to an embodiment.

FIG. 13 illustrates a configuration of a semiconductor manufacturing device according to an embodiment.

FIG. 14 illustrates a leakage magnetic field caused by electromagnets fixed on both sides by a magnetic field direction measuring device in a semiconductor manufacturing device according to an embodiment.

FIG. 15 illustrates a leakage magnetic field caused by electromagnets fixed on both sides by a magnetic field direction measuring device in a semiconductor manufacturing device according to an embodiment.

FIG. 16 illustrates a configuration of an observation microscope in a semiconductor manufacturing device according to an embodiment.

FIG. 17 illustrates the one-dimensional distribution of the angle of the horizontal magnetic field when cut at a certain coordinate on the Y-axis before and after defining the magnetic field direction from the measured Bx and Bz by a magnetic field direction measuring device. according to an embodiment.

FIG. 18 illustrates a vertical magnetization signal of a sample in a semiconductor manufacturing device according to an embodiment.

FIG. 19 illustrates verification of an anisotropic magnetic field (Hk) according to an embodiment.

FIG. 20 illustrates a configuration of a semiconductor manufacturing device according to an embodiment.

FIG. 21 illustrates a region of interest in a semiconductor manufacturing device according to an embodiment.

FIG. 22 illustrates the average luminance value of a measured sample in a semiconductor manufacturing device according to an embodiment of the present disclosure.

FIG. 23 illustrates the average luminance value of a measured sample in a semiconductor manufacturing device according to an embodiment of the present disclosure.

FIG. 24 illustrates the vertical magnetization of a sample in a semiconductor manufacturing device according to an embodiment of the present disclosure.

### DETAILED DESCRIPTION

Hereinafter, embodiments will be described with reference to the accompanying drawings.

When applying a horizontal or tilted magnetic field, other than a perpendicular magnetic field, to a PMA film used in a MRAM, it is known that the signal of the Kerr effect contains a mixture of polar Kerr effect, longitudinal Kerr effect, and transverse Kerr effect. However, in addition to multiple measurements, to measure the anisotropic magnetic field (Hk), a strong horizontal magnetic field should be applied to saturate the horizontal magnetization of the sample. The magnetic materials used in MRAM should be relatively large, as the electromagnets should output a horizontal magnetic field of at least 5 kOe. Moreover, the direction of the horizontal magnetic field should be exactly horizontal. Therefore, to separate the polar Kerr effect and the longitudinal Kerr effect with a leakage magnetic field maintained on one side rather than a large magnetic field, the yoke gap on the left and right is widened, the yoke diameter should be increased and the number of coil turns should be increased. As a result, the electromagnet becomes larger. It is challenging to accommodate such an electromagnet, which can output a horizontal magnetic field of 5 kOe or more, at a working distance of about 10 mm between the objective lens and the sample.

An overview of a semiconductor manufacturing device and a semiconductor manufacturing method according to embodiments will be described. A semiconductor manufacturing device of an embodiment includes a semiconductor wafer manufacturing device that includes a magnetic material film such as a perpendicular magnetic anisotropy (PMA) film, etc., or includes a semiconductor wafer inspection device that includes a magnetic material film. In addition, a semiconductor manufacturing device of an embodiment includes a manufacturing apparatus for a semiconductor memory device that includes a magnetoresistive random access memory (MRAM), and includes an inspection device for a semiconductor memory device that includes an MRAM. A semiconductor manufacturing device of an embodiment provides a semiconductor wafer and a semiconductor memory device for which magnetic properties can be measured with high precision and sensitivity.

As a method of measuring and evaluating the material of a magnetic film such as a PMA film, etc., optical measurement using a magneto-optical Kerr effect (MOKE) device is known, as described above. In an embodiment, the anisotropic magnetic field (Hk), which is measured and evaluated by destructive testing in a vibrating sample magnetometer (VSM), etc., is measured and evaluated in a semiconductor wafer.

In addition, in an embodiment, the anisotropic magnetic field (Hk) is measured using an extrapolation method. Accordingly, a semiconductor manufacturing device of an embodiment uses an electromagnet that outputs a relatively small magnetic field, and facilitates device constructions. Furthermore, a semiconductor manufacturing device of an embodiment sequentially measures and corrects the magnetic field direction of the sample, which increases the stability of continuous measurements and evaluations of the anisotropic magnetic field (Hk).

### Example 1

A semiconductor manufacturing device according to an embodiment will be described. The description of a semiconductor manufacturing device of an embodiment will include a Configuration description, a Sample description, and an Operation description.

### Configuration

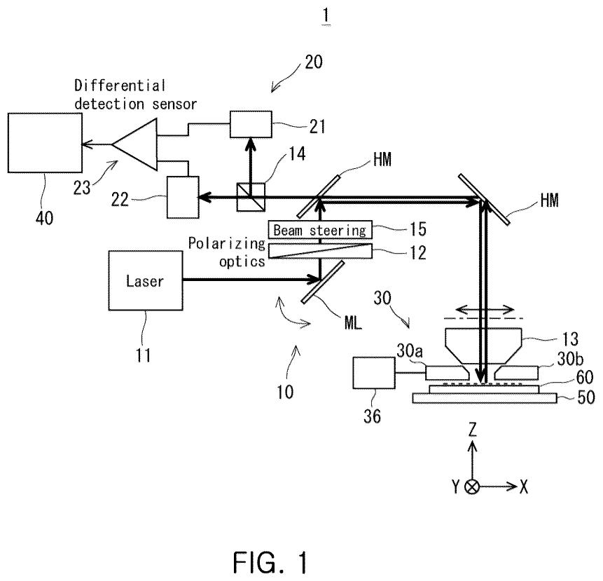

FIG. 1 illustrates a configuration of a semiconductor manufacturing device according to an embodiment. As illustrated in FIG. 1, a semiconductor manufacturing device 1 is, for example, a MOKE device. The semiconductor manufacturing device 1 includes an optical system 10, a detection unit 20, a magnetic field generating unit 30, and a derivation unit 40. The semiconductor manufacturing device 1 measures and evaluates magnetization characteristics of a sample 60 on a stage 50.

For convenience of description of the semiconductor manufacturing device 1, an XYZ orthogonal coordinate axis system is introduced. The direction vertical to the upper surface of the stage 50 is referred to as the Z-axis direction, the upper direction thereof is referred to as the +Z-axis direction, and the downward direction thereof is referred to as the −Z-axis direction. The plane normal to the Z-axis direction is referred to as the X-Y plane. The Z-axis direction is sometimes called the vertical direction. The direction parallel to the X-Y plane is sometimes called the horizontal direction.

The optical system 10 includes, for example, alight source 11, a polarizer 12, a half mirror (HM), an objective lens 13, and a polarizing beam splitter 14. In addition to these, the optical system 10 may also include optical elements such as a lens, mirror, a wave plate, a beam steering mechanism 15, etc.

The light source 11 is, for example, a laser light source. For example, the illumination light is laser light. The optical system 10 transmits the illumination light emitted from the light source 11 to the polarizer 12 through a mirror ML. The illumination light is converted into linearly polarized light that includes linear polarization. The linearly polarized illumination light illuminates the sample 60 through half mirrors (HM) and the objective lens 13.

The optical axis of the objective lens 13 extends in the Z-axis direction. The optical system 10 vertically illuminates the sample 60 with polarized illumination light. For example, the sample 60 is illuminated such that the main axis of the illumination light follows the optical axis of the objective lens 13. Light reflected from the sample 60 enters the polarizing beam splitter 14 through the objective lens 13 and the half mirrors (HM). The polarizing beam splitter 14 separates reflected light into a reflected light that includes s-polarization and a reflected light that includes p-polarization. The s-polarization reflected light and the p-polarization reflected light separated by the polarizing beam splitter 14 are detected by detectors 21 and 22, respectively of the detection unit 20.

The detection unit 20 includes detectors 21 and 22 and a signal analysis unit 23. The detection unit 20 simultaneously detects the polarization components of the s-polarized light and the p-polarized light using two detectors 21 and 22, respectively, and the polarization components are analyzed by the signal analysis unit 23. The signal analysis unit 23 configures a differential detection system. The detection unit 20 improves a signal to-noise (SN) ratio by controlling the configuration thereof using a lock-in-amp.

The optical system 10 guides the reflected light to the detection unit 20 when the magnetic field generated by the magnetic field generating unit 30 is applied to the sample 60. The polarization state of the reflected light is slightly modulated by the Kerr effect generated in the sample 60 by the magnetic field. In the magneto-optical Kerr effect measurement, the detection unit 20 detects the vertical magnetization response of the easy axis of the PMA film by positively and negatively sweeping the sample 60 with a first magnetic field or a magnetic field in an easy axis (Z-axis) direction. The extinction response of the PMA film is detected by positively and negatively sweeping the sample 60 with a second magnetic field or a magnetic field in a difficult axis (X-axis) direction. In this manner, the optical system 10 of an embodiment is configured as polar MOKE, which detects the polar Kerr effect by illumination light that is vertically incident to the sample 60. For example, the polar Kerr effect is a phenomenon in which the direction of polarization rotates when light passes through or is reflected from an object. A longitudinal Kerr effect occurs when light is vertically incident to the surface of a magnetic material and reflected. A transverse Kerr effect occurs when light is incident parallel to the surface of a magnetic material and is reflected.

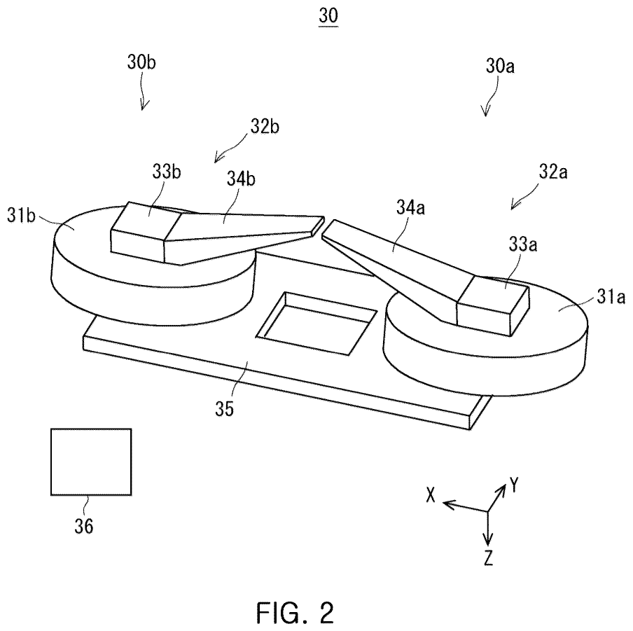

FIG. 2 is a perspective view of the magnetic field generating unit 30 in the semiconductor manufacturing device 1 according to an embodiment. As illustrated in FIG. 2, the magnetic field generating unit 30 includes, for example, two electromagnets 30a and 30b, and a control unit 36. In addition, as long as a perpendicular magnetic field that includes a vertical component and a horizontal magnetic field that includes a horizontal component as illustrated below can be formed, the magnetic field generating unit 30 is not limited to the two electromagnets 30a and 30b, and in other embodiments include more than two electromagnets, such as four electromagnets. The control unit 36 controls the current flowing through the plurality of electromagnets 30a and 30b.

The plurality of electromagnets 30a and 30b are disposed on a surface of the sample 60, which includes a wafer that has a front surface and a back surface. The electromagnets 30a and 30b apply a perpendicular magnetic field and a horizontal magnetic field to the sample 60 from the surface of the sample 60. The electromagnet 30a and the electromagnet 30b are disposed side by side in the X-axis direction. The electromagnets 30a and 30b include a coil 31a and a coil 31b, respectively. The coils 31a and 31b are collectively referred to as a coil 31. The control unit 36 controls the direction and magnitude of the current flowing through each coil 31, and applies a perpendicular magnetic field to saturate the vertical magnetization of the PMA film and a horizontal magnetic field to measure the extinction response to the sample 60.

The electromagnets 30a and 30b also include yokes 32a and 32b, respectively. The yokes 32a and 32b are collectively referred to as a yoke 32. The yoke 32 has L-shape, for example. The yoke 32 is L-shaped with vertical portions 33 that extend in the vertical direction and tilted portions 34 that are inclined with respect to the vertical direction. The yoke 32a includes a vertical portion 33a and a tilted portion 34a, and the yoke 32b includes a vertical portion 33b and a tilted portion 34b. The vertical portions 33a and 33b are collectively referred to as a vertical portion 33, and the tilted portions 34a and 34b are collectively referred to as a tilted portion 34. The tilted portions 34a and 34b extend parallel to the horizontal direction. The coil 31 is wound around the vertical portion 33 in a predetermined direction.

For example, the electromagnet 30a includes an L-shaped yoke 32a that includes a vertical portion 33a that extends in the vertical direction and a tilted portion 34a that is inclined with respect to the vertical direction, and a coil 31a wound on the vertical portion 33a in a predetermined direction. The electromagnet 30b includes an L-shaped yoke 32b that includes a vertical portion 33b that extends in the vertical direction and a tilted portion 34b that is inclined with respect to the vertical direction, and a coil 31b wound on the vertical portion 33b in a predetermined direction.

The vertical portions 33a and 33b pass through central axes of the electromagnets 30a and 30b, respectively. The upper ends of respective yokes 32a and 32b, for example, the upper ends of the vertical portions 33a and 33b, are connected to a connecting plate 35. The lower ends of the vertical portions 33a and 33b are connected to ends of the tilted portions 34a and 34b, respectively.

The tilted portion 34a of the yoke 32a and the tilted portion 34b of the yoke 32b extend in the X-axis direction. One end of the tilted portion 34a is connected to the lower end of the vertical portion 33a that passes through the center of the electromagnet 30a. Accordingly, the tilted portion 34a extends in the +X-axis direction from the lower end of the vertical portion 33a. One end of the tilted portion 34b is connected to the lower end of the vertical portion 33b that passes through the center of the electromagnet 30b. Accordingly, the tilted portion 34b extends in the −X-axis direction from the lower end of the vertical portion 33b. The other end of the tilted portion 34a and the other end of the tilted portion 34b face each other in the X-axis direction.

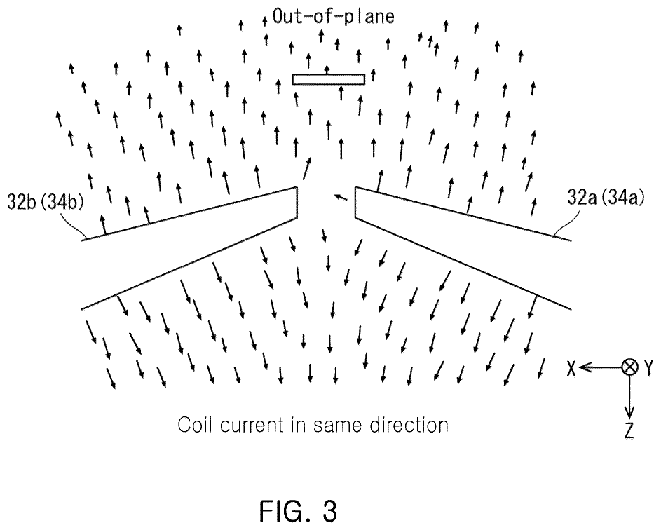

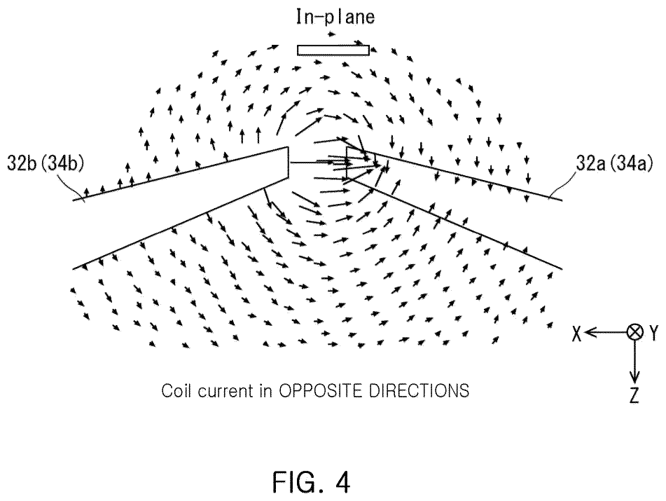

FIGS. 3 and 4 illustrate magnetic field simulation results of the magnetic field generated by the magnetic field generating unit 30 in the semiconductor manufacturing device 1 according to an embodiment. As illustrated in FIG. 3, for respective electromagnets 30a and 30b of the magnetic field generating unit 30, when a current flows in the direction of the current in-phase, a perpendicular magnetic field that includes a vertical component forms near the end of the yoke 32. In addition, as illustrated in FIG. 4, when a current flows in the direction of the current in opposite phase through the respective electromagnets 30a and 30b of the magnetic field generating unit 30, a horizontal magnetic field that includes a horizontal component forms near the end of the yoke 32.

The derivation unit 40 derives the anisotropic magnetic field (Hk) of the sample 60 based on the result detected by the detection unit 20. For example, the derivation unit 40 derives the anisotropic magnetic field (Hk) of the PMA film by extrapolating and fitting the extinction response of the sample 60.

### Sample

The sample 60 is, for example, a PMA film formed on a silicon wafer. The PMA film mimics a so-called free layer, a feature of devices that contain an MRAM. A typical PMA film contains, for example, soft magnetic CoFeB, etc. For example, the sample 60 has an MgO layer stacked on the upper and lower layers of CoFeB. In addition, the sample 60 has a metal cap layer stacked on the surface layer. The MgO layer is for obtaining a large tunnel magneto resistance effect (TMR effect).

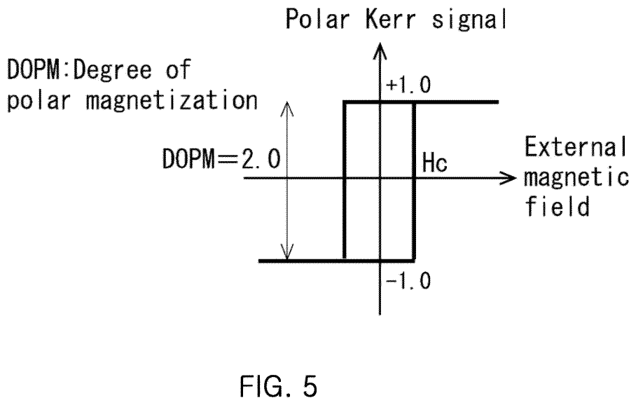

FIG. 5 illustrates the hysteresis loop of the vertical magnetization characteristics of the sample 60 in the semiconductor manufacturing device 1 according to an embodiment, and the magnetic field sweep pattern is, for example, 0→(+)→(−)→0→(+). The horizontal axis represents the external magnetic field in the vertical direction, and the vertical axis represents the vertical magnetization of the sample 60. In FIG. 5, the coercivity (or holding force) is illustrated as Hc. The range (range of change) of the amount of magnetization in the vertical direction is standardized and expressed as 2. In an embodiment of the present inventive concept, the range of magnetization in the vertical direction is called the degree of polar magnetization (DOPM). As illustrated in FIG. 5, when an external magnetic field in a vertical direction is applied to the sample 60, the vertical magnetization of the sample 60 illustrates a hysteresis loop.

### Operation

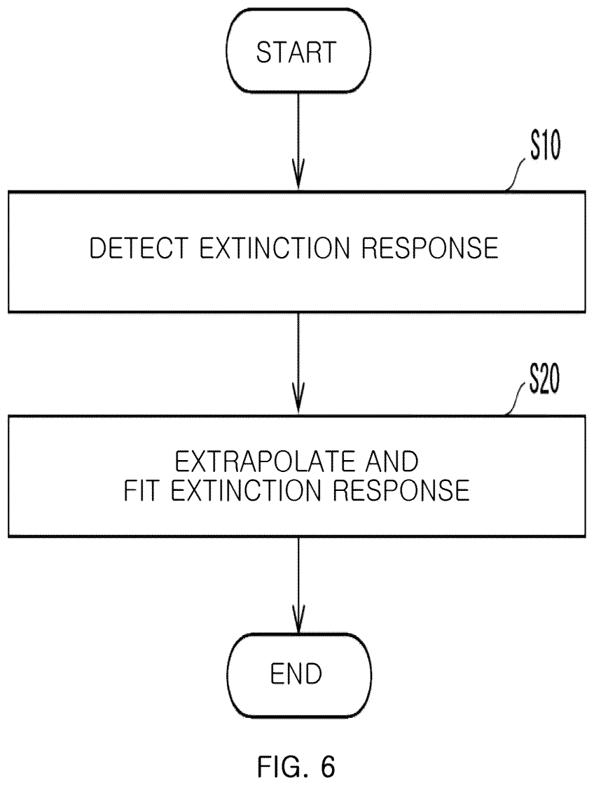

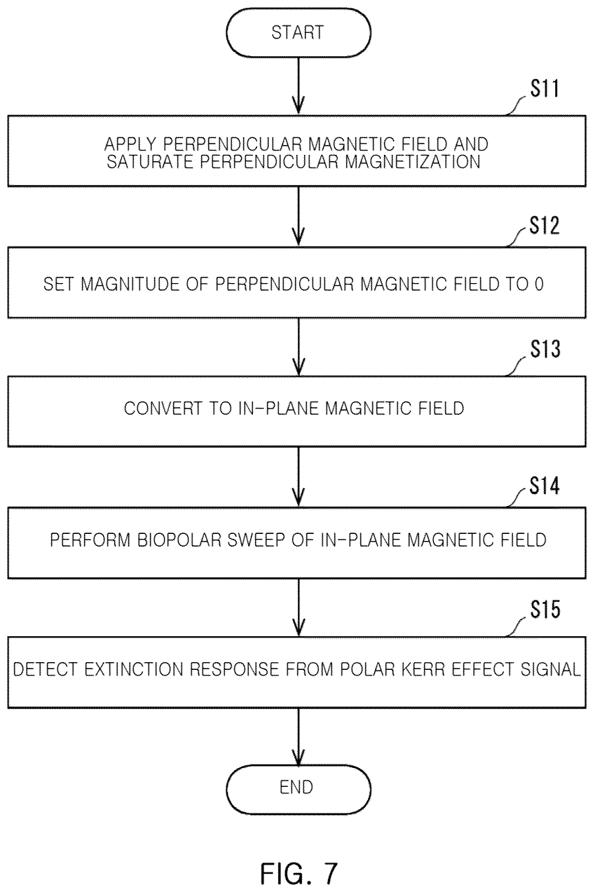

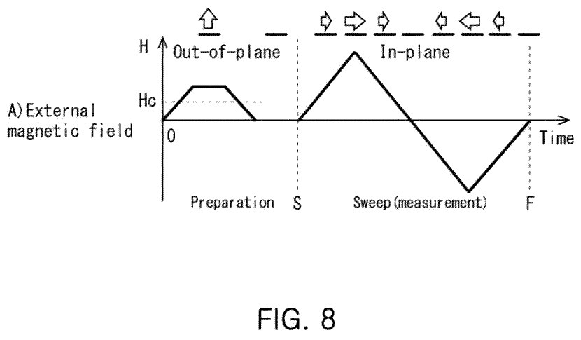

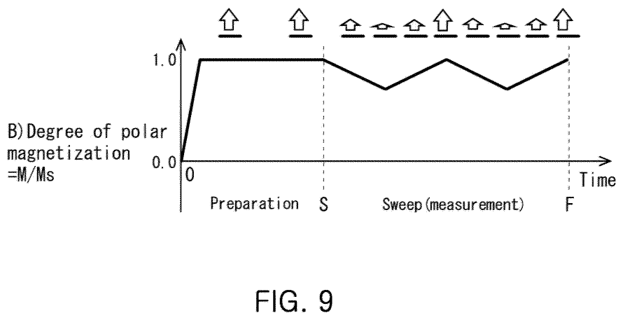

The operation of the semiconductor manufacturing device 1 according to an embodiment will be described. FIG. 6 is a flow chart of a semiconductor manufacturing method according to an embodiment. FIG. 7 is a flow chart of a method of detecting an extinction response in a semiconductor manufacturing method according to an embodiment. FIG. 8 illustrates a magnetic field applied to the sample 60 in the semiconductor manufacturing device 1 according to an embodiment, with the horizontal axis representing time and the vertical axis representing the strength of the magnetic field. FIG. 8 illustrates the direction of the applied magnetic field with an arrow. FIG. 9 illustrates the vertical magnetization of a sample in a semiconductor manufacturing device according to an embodiment, in which the horizontal axis represents time and the vertical axis represents the intensity of a normalized vertical magnetization signal. In FIG. 9, the direction and magnitude of the vertical magnetization of the sample 60 are indicated by arrows.

As illustrated in FIG. 6, the semiconductor manufacturing method according to an embodiment includes an operation of detecting an extinction response (S10) and an operation of extrapolating and fitting the extinction response (S20). As illustrated in FIG. 7, the operation of detecting the extinction response includes an operation of applying a perpendicular magnetic field and saturating vertical magnetization (S11), an operation of setting the magnitude of the perpendicular magnetic field to 0 (S12), an operation of converting to an in-plane horizontal magnetic field (S13), an operation of performing a bipolar sweep of the in-plane horizontal magnetic field (S14), and an operation of detecting an extinction response from a polar Kerr effect signal (S15), which will be described in detail with reference to FIGS. 8 and 9 below.

The times (t=0 to t=S) in FIGS. 8 and 9 are for preparation. The times (t=s to t=F) in FIGS. 8 and 9 are for measuring by performing a sweep of the magnetic field.

In the preparation operation of FIG. 8, the sample 60 is placed in a pre-extinguished state. The magnetic field generating unit 30 applies a perpendicular magnetic field that includes a vertical component to the sample 60. The control unit 36 controls the directions of currents in the electromagnets 30a and 30b to be in phase. For example, the control unit 36 gradually increases the perpendicular magnetic field. As illustrated in FIG. 9, the control unit 36 saturates the vertical magnetization of the PMA film by applying to the sample 60 a perpendicular magnetic field that is sufficiently greater than the coercivity (Hc) of the PMA film (operation S11). To sufficiently saturate the vertical magnetization of the sample 60, a magnetic field that is, for example, at least 10 times greater than the coercivity (Hc), is applied. The range (range of change) of the polar Kerr signal from the device state to the saturation state is recorded, and the intensity of the subsequent polar Kerr effect signal is standardized. The control unit 36, for example, sets the current flowing through the electromagnets 30a and 30b to 0 and sets the magnitude of the perpendicular magnetic field to 0 (operation S12). In addition, for a PMA film, the saturated vertical magnetization state is maintained even if the magnetic field is set to zero.

As illustrated in the sweep of FIG. 8, the control unit 36 changes the direction of the current in the electromagnets 30a and 30b in opposite phase. The control unit 36 converts the magnetic field applied to the sample 60 into a horizontal magnetic field that includes a horizontal component (operation S13). The control unit 36 gradually increases the magnitude of the applied horizontal magnetic field from 0. As illustrated in FIG. 9, the process of decreasing the vertical magnetization of the sample 60 is recorded as the intensity of the polar Kerr effect signal.

When the applied horizontal magnetic field is too large, or when there is an error in the direction of the horizontal magnetic field, a magnetization reversal, such as a reversal from upward magnetization to downward magnetization, called a break point occurs. Magnetization reversal occurs when the magnitude of the horizontal magnetic field exceeds a critical point. If magnetization reversal occurs, the physical model, which is a simultaneous rotation model of magnetization in a relatively small external magnetic field, and which is the premise of an embodiment of the present inventive concept, such as a reversible sweep, is destroyed. The anisotropic magnetic field (Hk) cannot be measured accurately because it deviates from the model equation of the extrapolation fitting. The control unit 36 performs a bipolar sweep that includes repeatedly increasing and decreasing the horizontal magnetic field magnitude several times to confirm and averaging the reversibility in the range where magnetization reversal does not occur (operation S14). The detection unit 20 detects the extinction response from the polar Kerr effect signal measured by bipolar sweep (operation S15, operation S10).

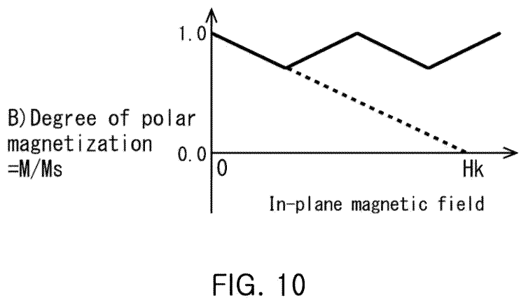

A process in which the vertical magnetization of the sample 60 is reduced is extrapolated. FIG. 10 illustrates the vertical magnetization of the sample 60 in the semiconductor manufacturing device 1 according to an embodiment. In FIG. 10, the horizontal axis represents the horizontal magnetic field and the vertical axis represents the strength of the normalized vertical magnetization signal. As illustrated in FIG. 10, when the applied horizontal magnetic field is gradually increased from 0, the derivation unit 40 extrapolates the process of decreasing the vertical magnetization of the sample 60. For example, the derivation unit 40 obtains the anisotropic magnetic field (Hk) from the intersection point between the extrapolated line and the horizontal axis. For example, the derivation unit 40 derives the anisotropic magnetic field (Hk) from the horizontal magnetic field value at which the magnetization amount becomes 0 by extrapolating and fitting the extinction response (operation S20).

As such, the semiconductor manufacturing device 1 of an embodiment performs measurement of the magneto-optical Kerr effect using a plurality of electromagnets 30a and 30b that electrically convert to a first magnetic field that includes a vertical component normal to the upper surface of the stage 50 and a second magnetic field that includes a horizontal component parallel to the upper surface of the stage 50, as the magnetic field applied to the sample 60 on the stage 50. The semiconductor manufacturing device 1 includes, in the corresponding magneto-optical Kerr effect measurement, a detection unit 20 that detects the extinction response of the PMA film in the sample 60, and a derivation unit 40 that derives the anisotropic magnetic field of the perpendicular magnetic anisotropy film by extrapolating and fitting the detected extinction response.

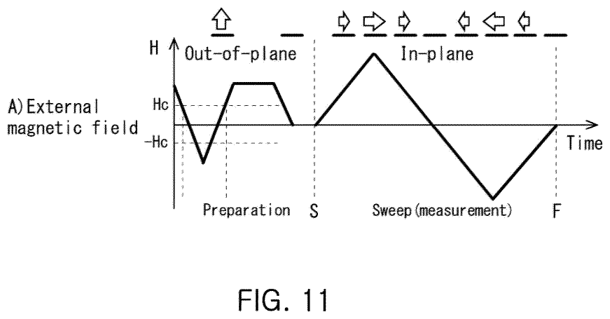

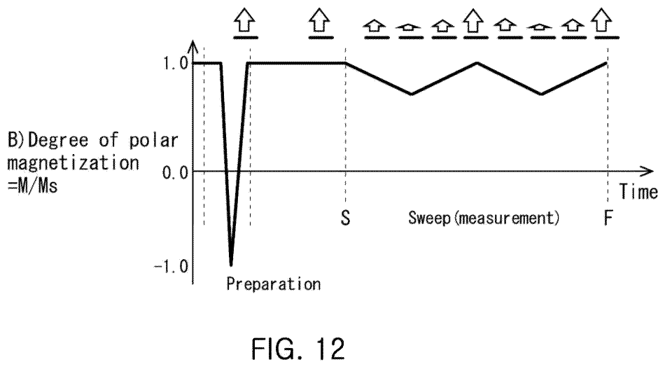

FIG. 11 illustrates a magnetic field applied to a sample 60 in a semiconductor manufacturing device 1 according to an embodiment, in which the horizontal axis represents time and the vertical axis represents the strength of the magnetic field. FIG. 12 illustrates the vertical magnetization of the sample 60 in the semiconductor manufacturing device 1 according to an embodiment, in which the horizontal axis represents time and the vertical axis represents strength of the normalized vertical magnetization signal.

Since the treatment takes time in FIGS. 8 and 9 described above, a hysteresis loop measurement magnetic field of the normal easy axis with +H→0→H→0→+H ending at +H magnetic field is applied, as a preparation, as illustrated in FIGS. 11 and 12. For example, the hysteresis loop of the easy axis is acquired in the preparation stage by measuring the normal polar Kerr effect, in addition to the saturation treatment of the vertical magnetization, which preprocesses the anisotropic magnetic field (Hk). Therefore, it is also possible to evaluate basic performance such as the magnitude of saturation magnetization and the holding force (or coercivity) (Hc) of the PMA film. The coercivity (Hc), which is at least somewhat correlated with the anisotropic magnetic field (Hk), can also be acquired at the same time. In addition, the vertical axis in FIGS. 9 and 12 represents the normalized vertical magnetization magnitude, and is standardized such that ½ of the maximum to minimum of the hysteresis loop in FIG. 5 becomes 1.

Effects of embodiments of the present inventive concept will be described. Previously, the anisotropic magnetic field (Hk) of the PMA film was obtained through destructive testing that uses VSM. However, in an embodiment of the present inventive concept, the anisotropic magnetic field (Hk) of the PMA film is measured using a magneto-optical method that uses a MOKE device as a non-destructive test. An embodiment of the present inventive concept uses a device method that measures an anisotropic magnetic field (Hk) in a relatively small magnetic field. Therefore, the anisotropic magnetic field (Hk) in the wafer can be measured and evaluated.

In an MRAM that uses a PMA film, the anisotropic magnetic field (Hk) is a characteristic factor that affects the driving speed as well as the reliability and durability of the MRAM. For this phenomenon, the anisotropic magnetic field (Hk) can be measured using a mechanical vibrating device called a VSM. However, the size of the sample 60 applicable to a VSM device is typically several 10 mm, and it is basically a destructive test as described above.

In addition, an anisotropic magnetic field (Hk) can be derived in a no-destructive magneto-optical method of testing. For example, measurements are made with vertical and horizontal magnetization characteristics mixed in the magneto-optical method. In addition, signals of vertical magnetization and horizontal magnetization can be separated by multiple measurements that change conditions such as the angle of incidence of the illumination light and the polarization direction of the illumination light. However, in addition to measuring multiple times, to measure the anisotropic magnetic field (Hk), it is necessary to saturate the horizontal magnetization of the sample 60 by applying a strong horizontal magnetic field. Magnetic materials used in MRAM require large electromagnets that output a horizontal magnetic field of at least 5 kOe.

In addition, the direction of the horizontal magnetic field at the measurement point of the sample 60 needs to be exactly horizontal. In addition to the conditions of such a large horizontal magnetic field and the exact direction of the horizontal magnetic field, to implement an electromagnet that can be measured in the wafer with the above-mentioned one-sided leakage magnetic field, it is necessary to widen the gap between the left and right yokes 32, increase the yoke diameter, and increase the number of turns of the coil, which makes the electromagnets 30a and 30b larger. Therefore, since there is a limit to the working distance between the objective lens 13 and the sample 60, it is challenging to configure such a device.

An extinction technique has been reported as a technique for measuring an anisotropic magnetic field (Hk) in a small applied magnetic field. For example, a sample is placed between opposing electromagnets, and the vertical magnetization is first saturated by applying a perpendicular magnetic field. Afterwards, the sample is rotated 90° to gradually increase the small horizontal magnetic field from zero and to measure the decrease in vertical magnetization, such as the extinction response. The anisotropic magnetic field (Hk) is derived from the intensity of the completely extinguished horizontal magnetic field obtained by extrapolating the extinction response. However, in a semiconductor manufacturing device operated in a wafer, it is not realistic to dispose opposing electromagnets and rotate the wafer, which is the sample 60.

The semiconductor manufacturing device 1 of an embodiment implements non-destructive measurement of the anisotropic magnetic field (Hk) by applying a magneto-optical method. In the semiconductor manufacturing device 1, the electromagnets 30a and 30b are disposed on one surface of the sample 60, rather than opposing surfaces. In addition, rather than rotating the sample 60, the direction of the magnetic field is rotated by electrical control without a driving mechanism. For example, the semiconductor manufacturing device 1 measures anisotropic magnetic field (Hk) in a wafer by disposing the electromagnets 30a and 30b on the surface of the sample 60 and controlling the direction of the current of the electromagnets 30a and 30b. In addition, in the semiconductor manufacturing device 1, the electromagnets 30a and 30b can be miniaturized by extrapolating the extinction response. In this manner, the semiconductor manufacturing device 1 of an embodiment can measure magnetic properties non-destructively and with high precision.

### Example 2

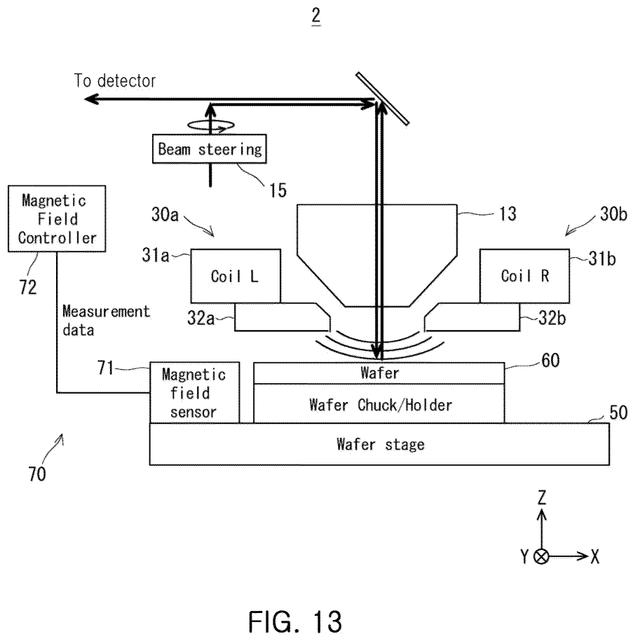

A semiconductor manufacturing device according to an embodiment will be described. FIG. 13 illustrates a configuration of a semiconductor manufacturing device according to an embodiment. As illustrated in FIG. 13, a semiconductor manufacturing device 2 of an embodiment further includes a magnetic field direction measuring device 70. The magnetic field direction measuring device 70 includes, for example, a magnetic field sensor 71 and a magnetic field controller 72. The magnetic field sensor 71 is disposed near the sample 60. For example, the upper surface of the magnetic field sensor 71 in the Z-axis direction is coplanar with the upper surface of the sample 60 in the Z-axis direction. The magnetic field direction measuring device 70 measures the magnetic field directions of the perpendicular magnetic field and the horizontal magnetic field. For example, the magnetic field direction measuring device 70 measures components in the horizontal magnetic field other than the horizontal direction. Other than the configuration illustrated in FIG. 13, the configuration of the semiconductor manufacturing device 2 is the same as that illustrated in FIG. 1.

In an above-described embodiment, the premise is that the direction of the horizontal magnetic field at the measurement point and the normal vector of the upper surface of the sample 60 are vertical. However, in reality, there are cases where that premise might not be satisfied. The reason is due to magnetic field leakage of one side. For example, as schematically illustrated by the magnetic field vector in FIG. 13, when the gap between the ends of the two yokes 32a and 32b is relatively small, and there is a predetermined gap between the yokes 32a and 32b and the sample 60, the magnetic field vector on the sample 60 is bent. For example, there are cases in which the premise of the above description only holds true at 1 point.

Since the upper surface of the sample 60 has flatness that satisfies industry standards, and the stage 50 is precisely horizontally adjusted, the reason why the above premise may only be established at one point is due to mechanical fixation of the electromagnets 30a and 30b in space, posture error, asymmetric errors of the magnetic field vector emitted from the yokes 32a and 32b, and errors in the setting position in the magnetic field space of the illumination light such, as the laser light, etc. Therefore, an embodiment of the present inventive concept includes a mechanism for correcting and controlling these errors.

The magnetic field sensor 71, called a magnetic field camera, measures, quantifies, and visualizes three-dimensional magnetic field vectors. An example of a magnetic field camera has a micro Hall sensor formed in an array shape. The measurement range of the magnetic field camera is 10 mm wide and vertical, and the X-Y spatial resolution is about 0.1 mm. Like a camera, a magnetic field camera can measure the three-dimensional magnetic field (magnetic flux density) of multiple points in batches.

For example, in the magnetic field sensor 71, a single-spot 3-axis Gauss meter is mounted on the stage 50 at the same height as the sample surface, and the three-dimensional magnetic field vector can be measured by step-moving and measuring the stage 50.

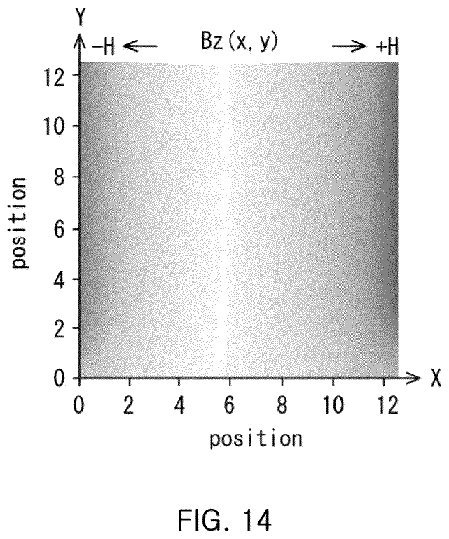

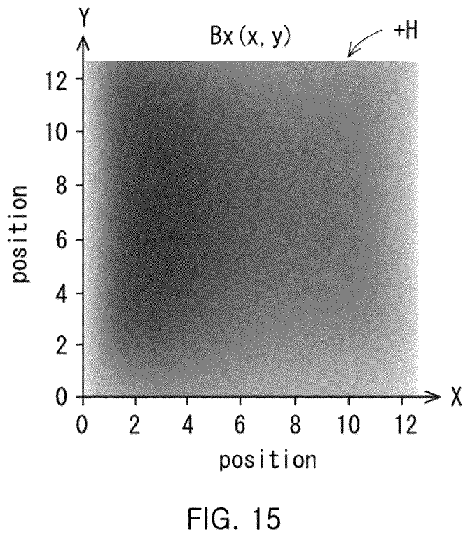

FIGS. 14 and 15 illustrate the leakage magnetic field caused by the electromagnets 30a and 30b fixed on both sides as measured by the magnetic field direction measuring device 70 in the semiconductor manufacturing device 2 according to an embodiment. FIG. 14 illustrates the magnetic field (magnetic flux density) Bz(x, y) in the Z-axis direction when a horizontal magnetic field is applied, and FIG. 15 illustrates the magnetic field Bx (x, y) in the X-axis direction when a horizontal magnetic field is applied.

For example, the central position of the measurement point measured by the magnetic field direction measuring device 70, the upper surface position of the sample 60, and the irradiation position of the illumination light are assumed to be managed in the X-Y coordinate system of the stage 50. In addition, the X coordinates and Y coordinates in FIGS. 14 and 15 are converted to predetermined values.

As illustrated in FIG. 14, the magnetic field Bz in the Z-axis direction when a horizontal magnetic field is applied is, for example, +H (upward) on the +X-axis direction side, and −H (downward) on the −X-axis direction side. As illustrated in FIG. 15, the magnetic field Bx in the X-axis direction when a horizontal magnetic field is applied is, for example, +H (upward) in the central portion and decreases in the peripheral portion.

Using this magnetic field direction measuring device 70, it is possible to measure Bx, By, and Bz at and near the irradiation position of the illumination light. Based on this measurement result, by interpolating the X coordinate on the magnetic field direction measuring device 70 where Bz is zero, which is the premise of an embodiment of the present inventive concept, leakage magnetic fields can be measured with sub-pixel level spatial resolution.

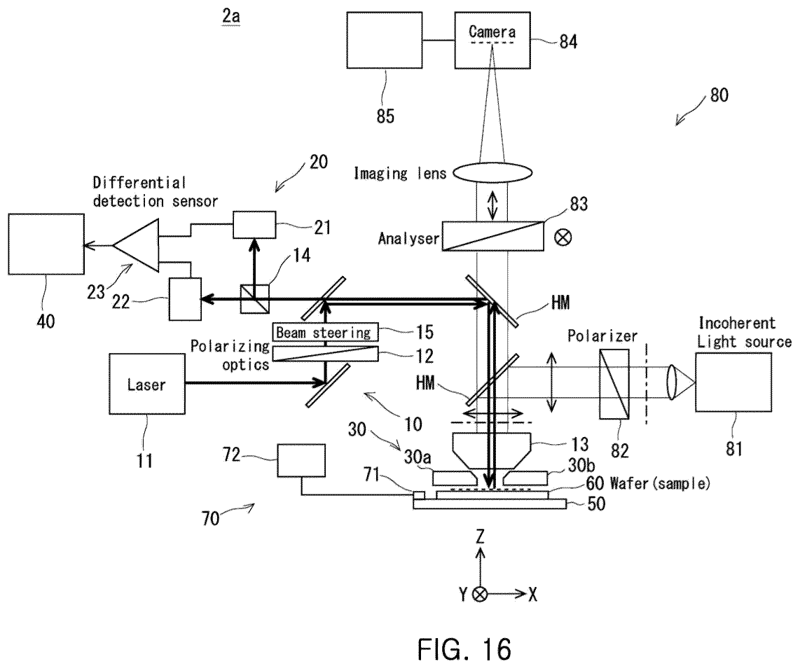

In addition, the irradiation position of the illumination light on the magnetic field direction measuring device 70 can also be confirmed with an observation microscope. FIG. 16 illustrates a configuration of an observation microscope in a semiconductor manufacturing device according to an embodiment. As illustrated in FIG. 16, a semiconductor manufacturing device 2a further includes an observation microscope 80 in addition to a configuration of the semiconductor manufacturing device 2. The observation microscope 80 includes a light source 81, a polarizer 82, an analyzer 83, an image acquisition unit 84, an image analysis unit 85, an objective lens 13, and a half mirror (HM). The image acquisition unit 84 acquires an image of the sample 60. The image analysis unit 85 analyzes changes in luminance values in the image. The configuration of FIG. 16 is otherwise substantially similar to that shown in FIG. 13, and descriptions of components described above may be summarized or omitted.

In an embodiment of the present inventive concept, the irradiation direction and irradiation position of the illumination light acquired by the observation microscope 80 and the direction and position of the horizontal magnetic field measured with the magnetic field direction measuring device 70 are controlled to be corrected by one of the three methods described below or by a combination of one or more of the three.

In a first control method (Cont. 1), by independently changing the current to left and right coils 31a and 31b, the position at which the magnetic field in the vertical direction in the horizontal magnetic field becomes Bz=0 is shifted. For example, based on the horizontal magnetic field measured with the magnetic field direction measuring device 70, the control unit 36 controls the current flowing through respective coils 31a and 31b such that the vertical component of the horizontal magnetic field becomes a minimum (for example, 0) at the laser spot position that corresponds to the sample measurement point.

In addition, in the control unit 36, during continuous magneto-optical Kerr effect measurements, the current flowing through each of the coils 31a and 31b is feedback-controlled at regular intervals, such that the vertical component of the horizontal magnetic field is minimized at predetermined intervals, for example, periodically. Therefore, the measurement of the magneto-optical Kerr effect can be stabilized.

In a second control method (Cont. 2), based on the horizontal magnetic field measured with the magnetic field direction measuring device 70, the tilt of the sample 60 on the stage 50 is controlled such that the horizontal component applied to the sample 60 is parallel to the sample film surface. For example, the wafer holder that chucks and holds the sample 60 is controlled to tilt in accordance with the direction of the horizontal magnetic field measured with the magnetic field direction measuring device 70.

For example, the stage 50 includes a wafer holder that adsorbs and holds the sample 60. In addition, the stage 50 is movable in the X-axis, Y-axis, and Z-axis directions, and can be rotatable around at least one of the X-axis, Y-axis, or Z-axis. This control method can be implemented with a leveling stage, etc., used in semiconductor exposure equipment, etc.

In addition, the stage 50 can feedback-control the tilt of the sample 60 such that the horizontal component becomes parallel to the sample surface at regular intervals during continuous magneto-optical Kerr effect measurements. For example, the tilt of the sample 60 can be feedback controlled such that the horizontal component is maximized in a measurement position illuminated by the illumination light. Therefore, the measurement of the magneto-optical Kerr effect can be stabilized.

In a third control method (Cont. 3), based on the horizontal magnetic field measured with the magnetic field direction measuring device 70, the optical path of the illumination light is moved to a position in which the vertical component of the horizontal magnetic field is minimized. For example, the optical system 10 has a beam steering mechanism 15 that changes the angle of the illumination light used to measure the magneto-optical Kerr effect. A transmission type beam steering mechanism 15 is a type used in, for example, light detection and ranging (LIDAR), etc, and can shift the spot position on the sample by fΔΘ by changing the angle of the illumination light by ΔΘ, where f is a focal length of the objective lens. The beam steering 15 moves the illumination spot light on the sample to a position in which the vertical component of the horizontal magnetic field is minimized, for example, 0. In addition, a control method in which the illumination spot light on the sample can be moved to a position in which the vertical component of the horizontal magnetic field is minimized is not limited to a method of controlling relative minute rotation of a pair of prisms, such as the transmission type beam steering 15 in the optical path of the optical system 10, but also applies to a method of moving the spot position of the illumination light using angle modulation of the illumination system bending mirror ML, etc.

In addition, the moving means such as the beam steering 15 can move the spot position of the illumination light to a position in which the vertical component of the horizontal magnetic field is minimized at regular intervals during continuous magneto-optical Kerr effect measurements. Therefore, the measurement of the magneto-optical Kerr effect can be stabilized.

In addition, correction control can be performed by combining at least two of the first control, the second control, and the third control methods. For example, by combining control of the current flowing through each coil and control of the tilt of the sample surface, excessive coil current control and excessive tilt angle control is prevented, where “excessive” indicates that the side effects are large and harmful effects occur. For example, when excessive coil current control occurs, the size of the magnetic field output from the left and right yokes is significantly different, and there is a difference in the amount of heat generated during continuous operations, causing side effects on stability.

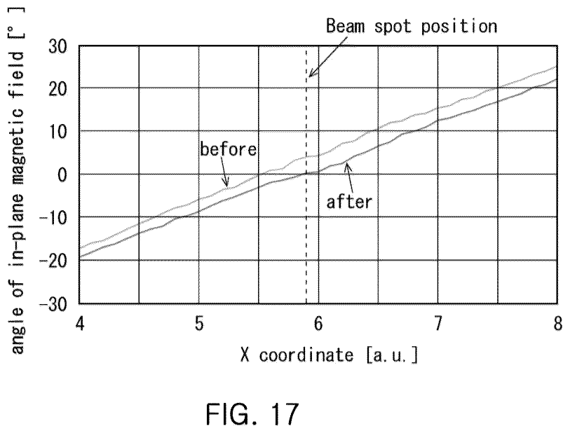

FIG. 17 illustrates a one-dimensional distribution of the angle of the horizontal magnetic field when cut at a predetermined coordinate on the Y axis, before and after defining the magnetic field direction from Bx and Bz measured with the magnetic field direction measuring device 70, in a semiconductor manufacturing device according to an embodiment of the present inventive concept. In FIG. 17, the horizontal axis represents the X-axis coordinate, and the vertical axis represents the angle of the horizontal magnetic field. As illustrated in the ‘before’ in FIG. 17, when the laser spot (irradiation position of the illumination light) is at the position of X=5.9 mm, the position of 5.5 mm is the ideal horizontal magnetic field before defining the magnetic field direction.

The magnetic field direction is about 4° at the position of the laser spot of X=5.9 mm, for example, in a measurement position that does not satisfy a premised horizontal magnetic field premised. Accordingly, as disclosed in Cont. 1 described above, the current balance of the electromagnets 30a and 30b is controlled. As a result, as illustrated in the ‘after’ in FIG. 17, the magnetic field distribution is controlled such that the laser spot becomes an ideal horizontal magnetic field.

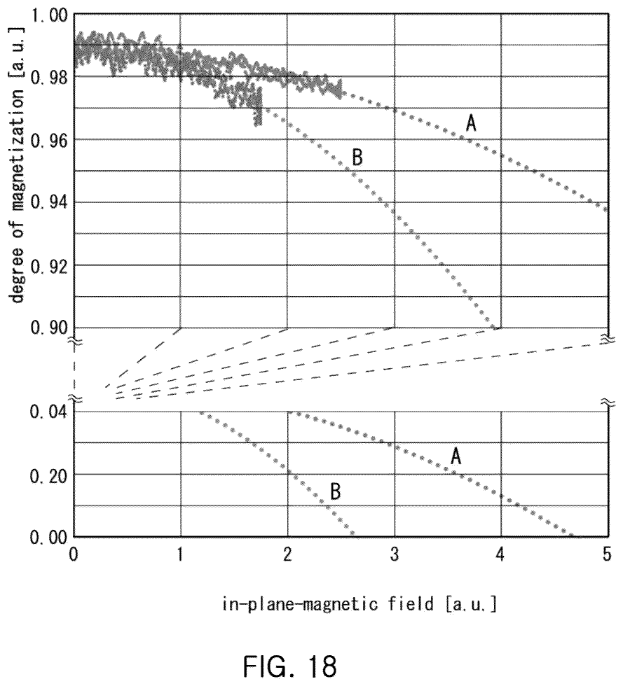

FIG. 18 illustrates a vertical magnetization signal of the sample 60 in a semiconductor manufacturing device 2 according to an embodiment of the present inventive concept. In FIG. 18, the horizontal axis represents the horizontal magnetic field, and the vertical axis represents the intensity of the normalized vertical magnetization signal. FIG. 18 illustrates the results of measuring two types of PMA films, sample A and sample B, with different anisotropic magnetic fields (Hk). In the measurement, the horizontal magnetic field within the break point is swept three times, similar to the operation of the semiconductor manufacturing device 1 according to an embodiment. As illustrated in FIG. 18, in all three sweeps, only data that returns to the intensity of the original vertical magnetization signal is used when the horizontal magnetic field is 0. In addition, the error in the direction of the horizontal magnetic field at the measurement point is accurately adjusted to the measurement position in which the magnetic field Bz is zero at the irradiation position of the illumination light, using Cont. 1, the electromagnet current control of Example 2.

One physical model for a first-order approximation of sin 2Θ that is effective for relatively small external magnetic fields can be applied to the PMA film for MRAM prepared for verification of an embodiment of the present inventive concept. In fact, as illustrated in FIG. 18, sufficient precision may be fitted with the first-order approximation of sin 2Θ. For the magnetic field that completely disappears by extrapolation, for example, Sample A and Sample B, the effective anisotropic magnetic field (Hk) may be detected as 4.7 kOe and 2.7 kOe, respectively.

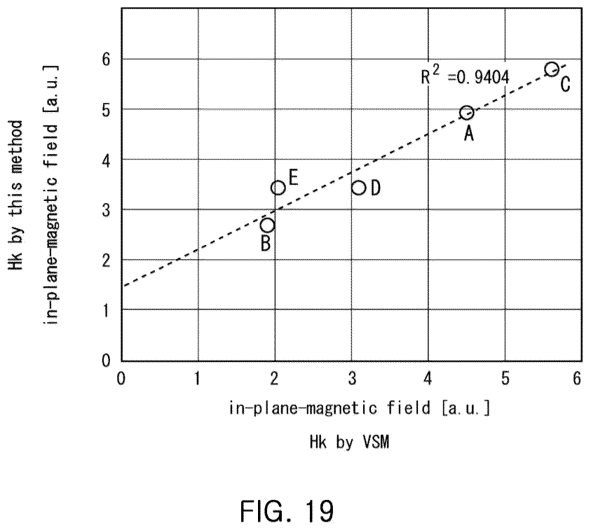

FIG. 19 illustrates the verification of the anisotropic magnetic field (Hk) according to an embodiment, in which the horizontal axis represents the anisotropic magnetic field (Hk) acquired by VSM, and the vertical axis represents the anisotropic magnetic field (Hk) obtained by a technique of an embodiment of the present inventive concept. As illustrated in FIG. 19, the measurement results of the VSM using five samples with different anisotropic magnetic fields (Hk), including the above-described sample A and sample B, and the measurement results of an embodiment of the present inventive concept, have a good correlation. Therefore, the effectiveness of a technique according to an embodiment is verified. In addition, in the VSM measurement, the physical definition was matched to a measurement technique of an embodiment of the present inventive concept by initially saturating the magnetization in the vertical direction rather than in the device, and then performing a bipolar sweep to start the horizontal magnetic field from 0.

### Example 3

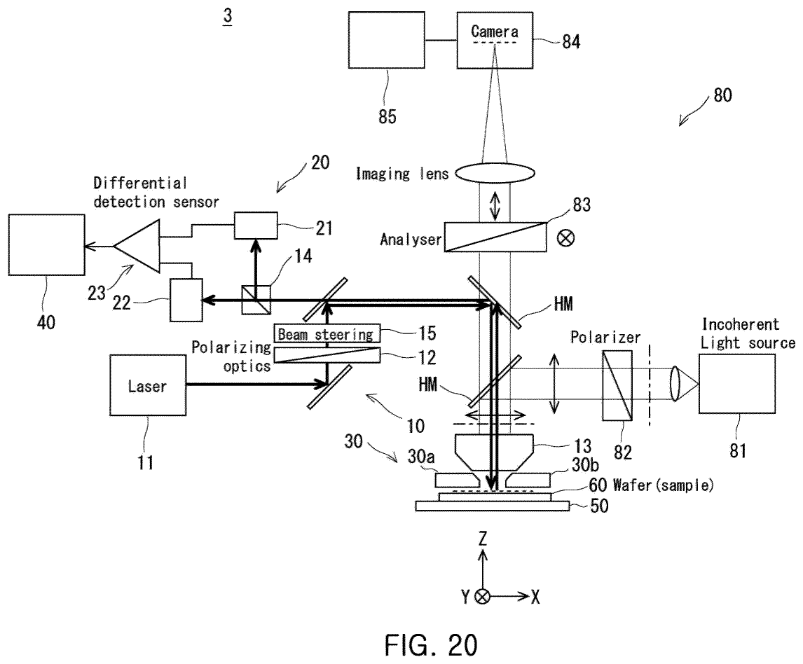

A semiconductor manufacturing device according to an embodiment will be described. In an embodiment described above, in addition to measuring the magnetic field direction on the sample 60 using a magnetic field direction measuring device 70 such as a magnetic field camera, an observation microscope was also used. FIG. 20 illustrates a configuration of a semiconductor manufacturing device according to an embodiment. As illustrated in FIG. 20, a semiconductor manufacturing device 3 of an embodiment further includes an observation microscope 80. As described above, the observation microscope 80 includes a light source 81, a polarizer 82, an analyzer 83, an image acquisition unit 84, an image analysis unit 85, an objective lens 13, and a half mirror (HM). The configuration of FIG. 20 is otherwise substantially similar to that shown in FIG. 1, and descriptions of components described above may be summarized or omitted.

The observation microscope 80 according to an embodiment is one of a polarizing microscope composed of a polarizer 82 and an analyzer 83 in a Cross Nicols arrangement, or a magnetic domain observation microscope. The observation microscope 80 not only observes the irradiation position of the illumination light on the sample 60, but also acquires an extinction ratio image while applying a magnetic field. In addition, the observation microscope 80 measures the hysteresis loop of magnetization response from the luminance response of the extinction ratio image.

For example, the observation microscope 80 acquires a hysteresis loop of the polar Kerr effect in an arbitrary region of interest, hereinafter referred to as an ROI, within the field of view. For example, the image acquisition unit 84 acquires an image of the sample 60 that includes a plurality of ROIs.

The image analysis unit 85 analyzes a change in luminance value for each ROI due to the magneto-optical Kerr effect. The observation microscope 80 also corrects the polarization error of the optical system of the observation microscope 80 for each ROI. This method can also be applied to the measurement of the anisotropic magnetic field (Hk) described above.

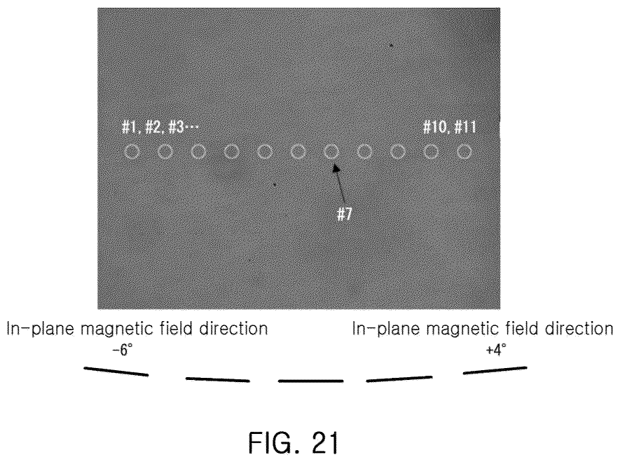

FIG. 21 illustrates ROIs within a field of view in the semiconductor manufacturing device 3 according to an embodiment of the present inventive concept. As illustrated in FIG. 21, the size of the field of view on the sample 60 is, for example, about 1 mm×0.8 mm. The ROIs to be analyzed are assumed to be, for example, 11 sweeps from #1 to #11 within the field of view. In addition, for example, the irradiation position of the illumination light is assumed to be at #6. Except for the frame in FIG. 21, the approximate angular error in the direction of the horizontal magnetic field is schematically illustrated. The sequence of the magnetic field applied to the sample 60 is the same as that illustrated in FIGS. 8 and 9 according to the above-described embodiment.

The sample 60 is vertically magnetized and a degree of polar magnetization, hereinafter referred to as DOPM, is acquired, and the hysteresis loop when measuring normal vertical magnetization is also measured. For example, the control unit 36 of the electromagnets applies and sweeps a perpendicular magnetic field that is greater than the coercivity (Hc) in the +Z-axis direction and −Z-axis direction. For example, the control unit 36 applies a perpendicular magnetic field to the sample 60 such that the image acquisition unit 84 acquires the hysteresis loop of the luminance value for each ROI. The image acquisition unit 84 acquires the hysteresis loop of the luminance value for each ROI.

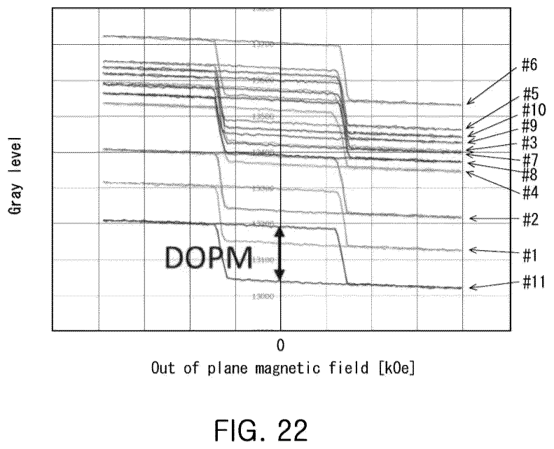

Pixel values are averaged for each measured ROI. FIG. 22 illustrates the average luminance value of the sample 60 measured in the semiconductor manufacturing device 3 according to an embodiment, in which the horizontal axis represents the applied perpendicular magnetic field and the vertical axis represents the average luminance value. As illustrated in FIG. 22, a hysteresis loop regarding the average luminance value is acquired for each measured ROI.

The DOPM of each ROI is obtained from FIG. 22. For example, the image analysis unit 85 acquires the DOPM (range of change) of the luminance value for each ROI from the hysteresis loop of the luminance value.

As shown in FIGS. 8 and 9, images are acquired while applying a horizontal magnetic field. For example, the control unit 36 switches to a horizontal magnetic field and increases the magnitude of the horizontal magnetic field from 0. In addition, the control unit 36 performs a bipolar sweep that includes an increase and a decrease in the magnitude of the horizontal magnetic field. The average luminance value for each ROI is acquired.

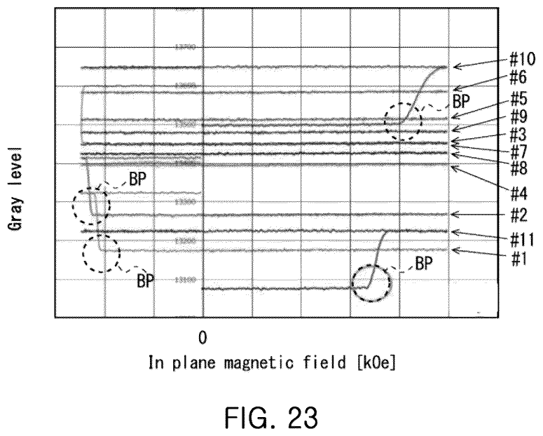

FIG. 23 illustrates the average luminance value of the sample 60 measured in the semiconductor manufacturing device 3 according to an embodiment, in which the horizontal axis represents the applied horizontal magnetic field, and the vertical axis represents the average luminance value. For example, the ROI of #11 at the right end of the field of view shows the appearance of a breakpoint BP, such as a magnetization reversal. In addition, the ROIs at both the left and right ends also indicate break points. The breakpoint is symmetrical with respect to the angular error of the horizontal magnetic field. Therefore, from these results, the ROI of #7 is the position on the sample 60 in the ideal horizontal magnetic field. In this manner, the image analysis unit 85 detects the ROI in which the vertical component of the horizontal magnetic field is minimized from the positions of the plurality of ROIs where magnetization reversal occurred in the bipolar sweep. The ROI with the minimum vertical component of the horizontal magnetic field is called a reference ROI.

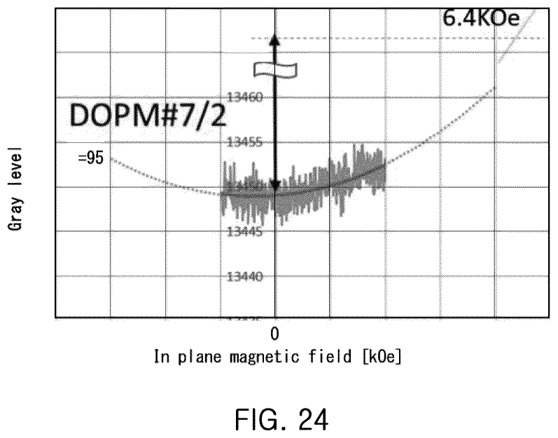

FIG. 24 illustrates the vertical magnetization of the sample 60 in the semiconductor manufacturing device 3 according to an embodiment. In FIG. 24, the horizontal axis represents the applied horizontal magnetic field, and the vertical axis represents the intensity of the vertical magnetization signal. FIG. 24 enlarges the portion where the horizontal magnetic field is 0 in ROI #7. From the measurement data in FIG. 22, the DOPM of #7 is 190GL (Gray level).

Therefore, the anisotropic magnetic field (Hk) is derived by extrapolating the value of the magnetic field that disappears at a displacement of 95GL, which is half of 190GL. For example, the image analysis unit 85 extrapolates and fits the luminance value of the reference ROI and acquires the anisotropic magnetic field (Hk) from a horizontal magnetic field that is ½ of the DOPM (range of change). The anisotropic magnetic field (Hk) detected in this manner is 6.4 kOe, and this value is matched to the measured value of the anisotropic magnetic field (Hk) in the VSM. In this manner, in an image-based evaluation method using the observation microscope 80, the anisotropic magnetic field (Hk) can also be measured and evaluated.

However, in an embodiment, by using an image-based technique, the X coordinate of the ideal horizontal magnetic field direction is obtained within the field of view, hereinafter referred to as the FOV. By using this result, alignment of the MOKE device can be performed. For example, in Cont. 3 of Example 2, above, the control of shift from position #6 to #7 is performed, based on the irradiation position of the illumination light at the image. For example, the beam steering 15 moves the spot position of the illumination light to a position in which the vertical component of the horizontal magnetic field is minimized.

In Cont. 1 and Cont. 2, the irradiation position of the illumination light is fixed, and thus by changing the current value of the electromagnets 30a and 30b or the tilt angle of the upper surface of the sample 60, the direction of the ideal horizontal magnetic field is iterated to match the irradiation position of the illumination light as described with reference to FIGS. 20 to 23 described above. By using techniques that use observation microscope images, the position of the illumination light and the position in which the perpendicular magnetic field becomes zero can be accurately matched, and the anisotropic magnetic field (Hk) can be detected from an extinction response measurement that uses laser light. For example, the magnetic field direction measuring device 70 as in Example 2 may be unnecessary.

### Example 4

Example 4 will now be described. When measuring the anisotropic magnetic field (Hk), if a non-destructive measurement can be performed using the MOKE device of an embodiment of the present inventive concept rather than a destructive measurement using a VSM, other characteristics of the PMA film in the sample 60 can be measured and evaluated. For example, a retention or thermal stability index A, which are important indicators in MRAM, can be measured and evaluated.

In an embodiment of the present inventive concept, the stage 50 includes additional heating and temperature measuring functions. For example, a commercially available heater is attached to a wafer chuck on the stage 50. The correction line between the set temperature of the heater and the temperature of the sample 60 is measured in advance. Based on this correction line, the temperature (T) of the sample 60 is controlled.

One method of detecting a temperature stability index A determines retention of an MRAM device by measuring the saturation magnetic field (Ms) and anisotropic magnetic field (Hk) at a plurality of temperatures (T) and fitting with respect to the temperature (T). In summary, the temperature stability index Δ can be detected by measuring the temperature dependence of the anisotropic magnetic energy (Ku) (unit: erg/cm3), which is a temperature dependence parameter, from Equations (1) and (2) below.

$$\\ \begin{matrix}Δ ( T ) = \frac{1}{2} [ Hk ( T ) + 4 π Ms ( T ) \times N ] \times Ms ( T ) \times V & Equation 1\end{matrix}$$

$$\\ \begin{matrix}Ms ( T ) = \frac{DOPM ( T )}{DOPM ( To )} Ms ( T 0 ) & Equation 2\end{matrix}$$

In the equations, Hk(T) is Hk at the set temperature (T) obtained from extrapolation fitting with the above described technique. Ms(T) is defined in Equation (2). Ms(T) is the saturation magnetization amount in the vertical direction at the set temperature (T) obtained from the ratio of the room temperature DOPM (TO) and the set temperature DOPM (T) obtained in the preparation step of this technique and the saturation magnetization in the vertical direction by VSM measurement measured at temperature (T). Normally, room temperature=T0. In Equation (1), V is the volume of the free layer of a single memory device called a magnetic tunnel junction (MTJ) at the MRAM device, N is the shape coefficient of the MTJ with a value from 0 to 1, and in this case, V and N may be considered as constants. TO in Equation (2) is the sample temperature when performing a VSM measurement.

A measurement flow according to an embodiment is as follows. (1) The temperature (Ti) is set. (2) At the temperature (Ti), the anisotropic magnetic field (Hk) is obtained by the saturation magnetization (Ms) (Ti) in the vertical direction, and the extinction response measurement results and extrapolation fitting as described with reference to FIGS. 6, 7 and expressed by Equation (2) is measured. The temperature stability index A is detected from Equation (1). For the PMA film in the sample 60, characteristics other than the anisotropic magnetic field (Hk) can be measured and evaluated.

Embodiments of the present inventive concept are not necessarily limited to Examples 1 to 4 above, and appropriate changes may be made without departing from the spirit of embodiments of the present inventive concept. For example, respective configurations of Examples 1 to 4 may be combined with each other.

As set forth above, in a semiconductor manufacturing device and a semiconductor manufacturing method according to embodiments, magnetic properties can be non-destructively measured with high precision.

While embodiments have been illustrated and described above, it will be apparent to those skilled in the art that modifications and variations can be made without departing from the scope of embodiments of the present inventive concept as defined by the appended claims.

1. A semiconductor manufacturing device for a magneto-optical Kerr effect measurement, comprising:
a plurality of electromagnets that electrically switch between a first magnetic field that has a component perpendicular to an upper surface of a stage upon which a sample is placed, and a second magnetic field that has a component parallel to the upper surface of the stage;
a detecting unit that detects an extinction response of a perpendicular magnetic anisotropy film in the sample from a polar Kerr effect signal; and
a derivation unit that derives an anisotropic magnetic field of the perpendicular magnetic antisotropy film by extrapolating and fitting the detected extinction response.

2. The semiconductor manufacturing device of claim 1, further comprising
a control unit that controls a current that flows through the plurality of electromagnets, saturates a vertical magnetization of the perpendicular magnetic anisotropy film by applying to the sample the first magnetic field whose magnitude is greater than a coercivity of the perpendicular magnetic anisotropy film,
sets the magnitude of the first magnetic field to be 0,
switches to the second magnetic field,
increases a magnitude of the second magnetic field from 0, and
performs a bipolar sweep that includes increasing and decreasing the magnitude of the second magnetic field a plurality of times, and
wherein the detection unit detects the extinction response from the polar Kerr effect signal measured by the bipolar sweep.

3. The semiconductor manufacturing device of claim 1, wherein the derivation unit derives the anisotropic magnetic field from the second magnetic field whose magnetization magnitude is by extrapolating and fitting the extinction response.

4. The semiconductor manufacturing device of claim 1, further comprising a control unit that controls a current flowing through the plurality of electromagnets, wherein the plurality of electromagnets are disposed on a surface of the sample that includes a wafer that has a front surface and a back surface, applies the first magnetic field and the second magnetic field to the sample from the surface of the sample,
wherein each electromagnet of the plurality of electromagnets includes a yoke and a coil, and
the control unit controls the direction and magnitude of the current that flows through each coil and applies to the sample the first magnetic field that saturates the vertical magnetization of the perpendicular magnetic anisotropy film, and the second magnetic field that obtains the extinction response.

5. The semiconductor manufacturing device of claim 4, further comprising a magnetic field sensor disposed adjacent to the sample, and a magnetic field direction measuring device that measures components of the second magnetic field other than the horizontal direction.

6. The semiconductor manufacturing device of claim 5, wherein, based on the second magnetic field measured by the magnetic field direction measuring device, the control unit controls the current flowing in each coil such that the vertical component of the second magnetic field is minimized in a measurement position illuminated by an illumination light.

7. The semiconductor manufacturing device of claim 5, wherein, based on the second magnetic field measured by the magnetic field direction measuring device, the stage controls a tilt of the sample such that the horizontal component of the second magnetic field is parallel to a sample surface in a measurement position illuminated by an illumination light.

8. The semiconductor manufacturing device of claim 5, further comprising a beam steering mechanism that moves a spot position of an illumination light used for the magneto-optical Kerr effect measurement,
wherein, based on the second magnetic field measured by the magnetic field direction measuring device, the beam steering mechanism moves the spot position of the illumination light to a position in which a vertical component of the second magnetic field is minimized in a measurement position illuminated by the illumination light.

9. The semiconductor manufacturing device of claim 5, further comprising a beam steering mechanism that moves a spot position of illumination light for the magneto-optical Kerr effect measurement,
wherein, based on the second magnetic field measured with the magnetic field direction measuring device,
the control unit controls current flowing in each coil such that a vertical component of the second magnetic field is minimized in a measurement position illuminated by the illumination light,
the stage controls a tilt of the sample such that a horizontal component of the second magnetic field is parallel to a sample surface in a measurement position illuminated with the illumination light, and
the beam steering mechanism moves a spot position of the illumination light to a position in which the vertical component of the second magnetic field is minimized in a measurement position illuminated by the illumination light.

10. The semiconductor manufacturing device of claim 6, wherein the control unit controls current flowing in each coil such that the vertical component of the second magnetic field is minimized at predetermined intervals during continuous magneto-optical Kerr effect measurements.

11. The semiconductor manufacturing device of claim 7, wherein the stage controls the tilt of the sample such that the horizontal component of the second magnetic field is parallel to the sample surface at predetermined intervals during continuous magneto-optical Kerr effect measurements.

12. The semiconductor manufacturing device of claim 8, wherein the beam steering mechanism moves the spot position of the illumination light to a position in which the vertical component of the second magnetic field is minimized at predetermined intervals during continuous magneto-optical Kerr effect measurements.

13. The semiconductor manufacturing device of claim 5, further comprising a beam steering mechanism that moves a spot position of illumination light used for the magneto-optical Kerr effect measurement,
wherein, based on the second magnetic field measured with the magnetic field direction measuring device,
the control unit controls current flowing in each coil such that a vertical component of the second magnetic field is minimized in a measurement position illuminated with an illumination light at predetermined intervals during continuous magneto-optical Kerr effect measurements,
the stage controls a tilt of the sample such that a horizontal component of the second magnetic field is parallel to a sample surface in a measurement position illuminated with the illumination light at predetermined intervals during continuous magneto-optical Kerr effect measurements, and
the beam steering mechanism controls movement of a spot position of the illumination light to a position in which the vertical component of the second magnetic field is minimized in a measurement position illuminated by the illumination light at predetermined intervals during continuous magneto-optical Kerr effect measurements.

14. The semiconductor manufacturing device of claim 4, further comprising:
an image acquisition unit that acquires an image of the sample that includes a plurality of regions of interest; and
an image analysis unit that analyzes a change in a luminance value for each region of interest due to a magneto-optical Kerr effect,
wherein the control unit
applies the first magnetic field to the sample such that the image acquisition unit acquires a hysteresis loop of the luminance value for each region of interest,
switches to the second magnetic field and increases a magnitude of the second magnetic field from 0, and
performs a bipolar sweep that includes increasing and decreasing the magnitude of the second magnetic field, and
wherein the image analysis unit,
obtains a change range of the luminance value for each region of interest from an extinction response of the luminance value,
detects a reference region of interest in which a vertical component of the second magnetic field is a minimum in the region of interest from positions of the plurality of regions of interest in which magnetization reversal occurred in the bipolar sweep,
extrapolates and fits the luminance value of the reference region of interest, and
acquires the anisotropic magnetic field from the second magnetic field at ½ of the change range.

15. The semiconductor manufacturing device of claim 14, further comprising a beam steering mechanism that moves an optical path of an illumination light used for the magneto-optical Kerr effect measurement,
wherein the beam steering mechanism moves a spot position of the illumination light to a position in which the vertical component of the second magnetic field is minimized.

16. The semiconductor manufacturing device of claim 1, wherein
the stage includes additional heating and temperature measuring functions, and
the derivation unit detects a thermal stability index from a relationship between a temperature of the sample and the anisotropic magnetic field.

17-32. (canceled)

33. A semiconductor manufacturing device for a magneto-optical Kerr effect measurement, comprising:
a detecting unit that detects an extinction response of a perpendicular magnetic anisotropy film in a sample from a polar Kerr effect signal in a magneto-optical Kerr effect measurement that uses a plurality of electromagnets that electrically switch between applying a first magnetic field and a second magnetic field to the sample on a stage, wherein the magnetic field includes a vertical component normal to an upper surface of the stage and the second magnetic field includes a horizontal component parallel to the upper surface of the stage; and
a derivation unit that derives an anisotropic magnetic field of the perpendicular magnetic anisotropy film by extrapolating and fitting the detected extinction response.

34. The semiconductor manufacturing device of claim 33, wherein the detecting unit:
applies the first magnetic field to the sample, wherein a magnitude of the first magnetic field is greater than a coercivity of the perpendicular magnetic anisotropy film, and saturates vertical magnetization of the perpendicular magnetic anisotropy film;
sets a magnitude of the first magnetic field to 0;
switches to the second magnetic field;
increases a magnitude of the second magnetic field from 0;
performs a bipolar sweep that includes increasing and decreasing the magnitude of the second magnetic field a plurality of times; and
detects an extinction response from the polar Kerr effect signal measured by the bipolar sweep.

35. The semiconductor manufacturing device of claim 33, wherein the deriving unit derives the anisotropic magnetic field from the second magnetic field in which a magnetization magnitude is 0 by extrapolating and fitting the extinction response.

36. The semiconductor manufacturing device of claim 33, wherein the plurality of electromagnets are disposed on a surface of the sample that includes a wafer that has a front surface and a back surface, and applies the first magnetic field and the second magnetic field to the sample from the surface of the sample,
wherein each electromagnet includes a yoke and a plurality of coils, and
wherein the detecting unit detects the extinction response of the perpendicular magnetic anisotropy film in the sample by applying the first magnetic field and the second magnetic field, to the sample by controlling a direction and a magnitude of current flowing in each coil.
